(19) United States
(12) Patent Application Publication
(10) Pub. No.: US 2009/0275146 A1
(43) Pub. Date: Nov. 5, 2009

(54) METHOD AND APPARATUS FOR MANUFACTURING DEVICE

(75) Inventors: Katsuo TAKANO, Kai-shi (JP); Takeshi KOKUBUN, Suwa-gun (JP); Yutaka KOKAZE, Susono-shi (JP); Masahisa UEDA, Susono-shi (JP); Mitsuhiro ENDOU, Susono-shi (JP); Koukou SUU, Susono-shi (JP); Toshiya MIYAZAKI, Susono-shi (JP); Toshiyuki NAKAMURA, Susono-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignees: ULVAC, Inc., Chigasaki-shi (JP); Seiko Epson Corporation, Tokyo (JP)

(21) Appl. No.: 12/428,096

(22) Filed: Apr. 22, 2009

(30) Foreign Application Priority Data
Apr. 23, 2008 (JP) 2008-112704

(51) Int. Cl. H01L 21/28; H01L 43/12; H01L 21/306

(52) U.S. Cl. 438/3; 156/345.31; 257/E21.158; 257/E43.006

(57) ABSTRACT

A method for manufacturing a device, includes: (A) forming a first electrode layer on a substrate; (B) forming a ferroelectric layer on the first electrode layer; (C) forming a second electrode layer on the ferroelectric layer; (D) forming a mask having a predetermined pattern on the second electrode layer; (E) forming a memory element by selectively removing the first electrode layer, the ferroelectric layer, and the second electrode layer using the mask; and (F) removing the mask, where at least, the processes (D) and (E), or the processes (E) and (F) are continuously performed under a reduced pressure.

The entire disclosure of Japanese Patent Application No. 2008-112704, filed Apr. 23, 2008, is expressly incorporated by reference herein.

### BACKGROUND OF THE INVENTION

1. Field of the Invention

The present invention relates to a method and an apparatus for manufacturing a device. More specifically, the invention relates to a preferred method and a preferred apparatus for manufacturing devices used when a memory element of a ferroelectric memory referred to as a FeRAM (Ferroelectric Random Access Memory), or devices such as, a sensor, an actuator, an oscillator, a filter, a piezo element are formed.

This application is based on and claims priority from Japanese Patent Application No. 2008-112704, filed on Apr. 23, 2008, the contents of which are incorporated herein by reference.

2. Background Art

Conventionally, as a type of nonvolatile memory, ferroelectric memory which is referred to as a FeRAM (ferroelectric random access memory) is known. In the ferroelectric memory, a memory element having a layered structure constituted of a lower electrode layer, a ferroelectric layer, and an upper electrode layer on a foundation layer of a substrate. By supplying a predetermined voltage between the lower electrode layer and the upper electrode layer, the ferroelectric memory causes the ferroelectric layer to generate spontaneous polarization, and write or clear information due to the spontaneous polarization. The ferroelectric memory has an advantage in that it is possible to write or clear information with a high-speed at a low voltage compared to conventional flash memory. When manufacturing the ferroelectric memory, it is possible to form a mask as a result of patterning by etching at a normal temperature.

In contrast, since it is impossible to form the memory element as a result of patterning by etching at a normal temperature, it is necessary to form the memory element at a high temperature. As a conventional method for manufacturing a ferroelectric memory, for example, a method disclosed in Japanese Unexamined Patent Application, First Publication No. 2006-344785 is known. In this method, a foundation layer made of an insulator is formed on a substrate, a lower electrode layer made of a noble metal such as Pt, a ferroelectric layer made of PZT (Pb(Zr, Ti)O₃), and an upper electrode layer made of a noble metal such as Pt are formed on the foundation layer in this order, and a stacked film is thereby obtained. Furthermore, a mask material layer made of oxidized silicon or the like is stacked on the stacked film, and a mask having a predetermined pattern is formed by etching the mask material layer at a normal temperature. Subsequently, as a result of etching the stacked film at a high temperature by using an apparatus different from the apparatus used in the above-described processes, a memory element made of a layered structure constituted of the lower electrode layer, the ferroelectric layer, and the upper electrode layer is formed.

However, in a conventional method for manufacturing a ferroelectric memory, an apparatus for patterning the mask material layer and etching at a normal temperature (hereinafter, referred as normal-temperature etching chamber) is used, and an apparatus for patterning the stacked film at a high temperature and etching at a high temperature (hereinafter, referred as high-temperature etching chamber) is used. As a result, it is necessary to extract the completed substrate to be etched at a normal temperature from the normal-temperature etching chamber, and to once again place the substrate in the high-temperature etching chamber. There are problems in that such processes are complicated and the apparatus structure is complex.

### SUMMARY OF THE INVENTION

The invention was made in order to solve the above-described problem, and has an object to provide a method and an apparatus for manufacturing a device, where processes greater than or equal to two of a process of forming a mask, a process of forming a memory element, and a process of removing the mask in an apparatus, are continuously performed, as a result, the number of processes is eliminated as compared with conventional methods, the manufacturing time is shortened, the apparatus structure is simplified, and it is possible to effectively manufacture a device at a low cost in a short time as compared with conventional methods.

The inventors have fully considered a method and an apparatus for manufacturing a device having a layered structure including a first electrode layer, a ferroelectric layer, and a second electrode layer. As a result, the inventors have found that, due to continuously performing two or more processes of forming a mask, forming a memory element, and removing the mask under reduced pressure, the processes for manufacturing the device are simplified, and it is also possible to simplify an apparatus structure and effectively manufacture the device at a low cost in a short time as compared with conventional methods; thereby the inventors have completed the invention.

A first aspect of the invention provides a method for manufacturing a device, including: forming a first electrode layer on a substrate (process A); forming a ferroelectric layer on the first electrode layer (process B); forming a second electrode layer on the ferroelectric layer (process C); forming a mask having a predetermined pattern on the second electrode layer (process D); forming a memory element by selectively removing the first electrode layer, the ferroelectric layer, and the second electrode layer using the mask (process E); and removing the mask (process F). In the method, at least, the processes D and E, or the processes E and F are continuously performed under a reduced pressure.

In the method for manufacturing a device, since at least, the processes D and E, or the processes E and F are continuously performed under reduced pressure, superfluous processes such as a process for transferring a substrate to another process are eliminated in two or more continuous processes. Consequently, the number of the manufacturing processes is eliminated, manufacturing time can be shortened, and the cost of the manufacturing process is reduced. As a result, it is possible to effectively manufacture a device at a low cost in a short time as compared with conventional methods.

It is preferable that, in the method of the first aspect of the invention, the process D and the process F be performed at a normal temperature, and the process E be performed at a high temperature.

It is preferable that, in the method of the first aspect of the invention, the process D, the process E, and the process F be continuously performed under a reduced pressure.

It is preferable that the method of the first aspect of the invention further include preheating the substrate (process G) at a stage previous to the process E.

It is preferable that, in the method of the first aspect of the invention, a chamber in which the process E is performed be different from a chamber in which the process G is performed, and the process E and the process G be continuously performed under a reduced pressure.

It is preferable that, in the method of the first aspect of the invention, a gas remaining in the substrate is removed at a stage subsequent to the process F in a chamber different from the chamber in which the process F is performed.

It is preferable that, in the method of the first aspect of the invention, the first electrode layer and the second electrode layer include one, two, or more selected from the group consisting of platinum, iridium, ruthenium, rhodium, palladium, osmium, iridium oxide, ruthenium oxide, and strontium ruthenate; and the ferroelectric layer be one selected from the group consisting of PZT (Pb(Zr, Ti)O₃), SBT (SrBi₂Ta₂O₉), BTO (Bi₄Ti₃O₁₂), BLT ((Bi, La)₄Ti₃O₁₂), and BTO (BaTiO₃).

A second aspect of the invention provides an apparatus for manufacturing a device, including: a transfer chamber including a transfer mechanism transferring a substrate; a normal-temperature etching chamber coupled to the transfer chamber; a high-temperature etching chamber coupled to the transfer chamber; and one or more load lock chambers coupled to the transfer chamber. In the apparatus, the transfer mechanism continuously transfers the substrate between the normal-temperature etching chamber, the high-temperature etching chamber, and the load lock chamber under vacuum.

In the apparatus for manufacturing a device, the normal-temperature etching chamber, the high-temperature etching chamber, and one or more load lock chambers are coupled to the transfer chamber including the transfer mechanism transferring the substrate. The transfer mechanism continuously transfers the substrate under vacuum between the normal-temperature etching chamber, the high-temperature etching chamber, and the load lock chamber. In this structure, it is possible to continuously perform the etching at a normal temperature, the etching at a high temperature, or the like under vacuum using one apparatus. In addition, as compared with the case of using a plurality of conventional apparatuses, time and cost required for transferring a substrate between these apparatuses, starting up an apparatus of post-processes, or the like are eliminated. As a result, it is possible to effectively manufacture a device at a low cost in a short time as compared with conventional apparatuses.

It is preferable that the apparatus of the second aspect of the invention further include: an ashing chamber and a pre-heat chamber. In the apparatus, either or both of the ashing chamber and the pre-heat chamber is provided at the transfer chamber, and the transfer mechanism continuously transfers the substrate under vacuum between the ashing chamber, the pre-heat chamber, the normal-temperature etching chamber, the high-temperature etching chamber, and the load lock chamber.

According to the method for manufacturing a device of the invention, the method includes: the process D in which the mask having a predetermined pattern is formed on the second electrode layer; the process E in which the first electrode layer, the ferroelectric layer, and the second electrode layer are selectively removed using the mask, the memory element is thereby formed; and the process F in which the mask is removed. In the processes D, E, and F, since at least, the processes D and E, or the processes E and F are continuously performed under reduced pressure, the number of the manufacturing processes is eliminated, a manufacturing time can be shortened, and it is possible to reduce the cost of the manufacturing process. Therefore, it is possible to effectively manufacture a device at a low cost in a short time as compared with conventional methods.

According to the apparatus for manufacturing a device of the invention, the normal-temperature etching chamber, the high-temperature etching chamber, and one or more load lock chambers are coupled to the transfer chamber including the transfer mechanism transferring the substrate. The transfer mechanism continuously transfers the substrate between the normal-temperature etching chamber, the high-temperature etching chamber, and the load lock chamber under vacuum. In this structure, it is possible to continuously perform the etching at a normal temperature, the etching at a high temperature, or the like under vacuum using one apparatus, and it is possible to eliminate the time and cost required for all processes. Therefore, it is possible to effectively manufacture a device at a low cost in a short time as compared with conventional apparatuses.

### BRIEF DESCRIPTION OF THE DRAWINGS

FIG. 1 is a schematic view showing a normal-temperature and high-temperature etching apparatus of an embodiment of the invention.

FIGS. 2A to 2E are cross-sectional views showing a method for forming a memory element of a ferroelectric memory of an embodiment of the invention.

### DESCRIPTION OF THE PREFERRED EMBODIMENTS

A method and an apparatus for manufacturing a device of the invention of an embodiment will be described.

In this embodiment, in order to easily understand the spirit of invention, the invention is specifically described. However, the invention is not limited to this embodiment without designation in particular. In addition, in these drawings which are utilized in the following explanation, appropriate changes have been made in the scale of the various members, in order to represent them at scales at which they can be easily understood.

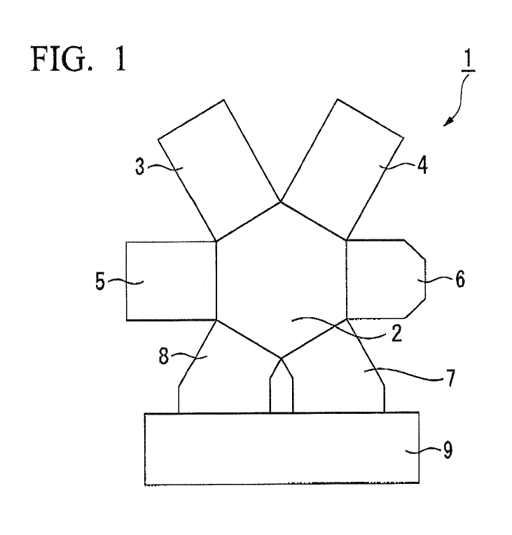

FIG. 1 is a schematic view showing an apparatus in which etching is performed at a normal temperature and at a high temperature, that is, an apparatus for manufacturing a device of an embodiment of the invention (hereinafter, referred as normal-temperature and high-temperature etching apparatus).

This normal-temperature and high-temperature etching apparatus 1 is an apparatus forming a device that has a layered structure in which a ferroelectric is held between a pair of electrodes by dry etching a multilayer film on a silicon substrate, that is, a memory element of a ferroelectric memory which is referred to as a FeRAM (ferroelectric random access memory).

The normal-temperature and high-temperature etching apparatus 1 includes a transfer mechanism (not shown) transferring a silicon substrate, and is constituted of transfer chamber 2 shaped in a regular-hexagonal form viewed from in a direction vertical to the apparatus, a normal-temperature etching chamber 3, a high-temperature etching chamber 4, an ashing chamber 5, a pre-heat chamber 6, an import load lock chamber 7, and an export load lock chamber 8, that are coupled to side walls of the transfer chamber 2, and an autoloader 9.

The transfer chamber 2 transfers the silicon substrate that is imported from the import load lock chamber 7 in order of manufacturing processes, between the normal-temperature etching chamber 3, the high-temperature etching chamber 4, the ashing chamber 5, and the pre-heat chamber 6. In the transfer chamber 2, the silicon substrate is continuously transferred under vacuum.

The normal-temperature etching chamber 3 is a chamber in which dry etching is performed at a normal temperature such as in the range of 10° C. to 80° C., and is preferably used when, for example, a mask, a foundation layer, or the like is dry etched.

The high-temperature etching chamber 3 is a chamber in which dry etching is performed at a high temperature such as in the range of 250° C. to 450° C., and is preferably used when, for example, the memory element of the ferroelectric memory is formed by dry etching a multilayer film.

The ashing chamber 5 is a chamber used when an organic film such as a photo resist is removed.

The pre-heat chamber 6 is a chamber used when, before transferring the silicon substrate on which the multilayer film is formed to the high-temperature etching chamber 3, the silicon substrate on which the multilayer film is formed is preheated so as to reach a predetermined temperature.

Since the transfer chamber 2 is coupled to the above-described chambers 3 to 6, it is possible to continuously use the chambers 3 to 6 under vacuum.

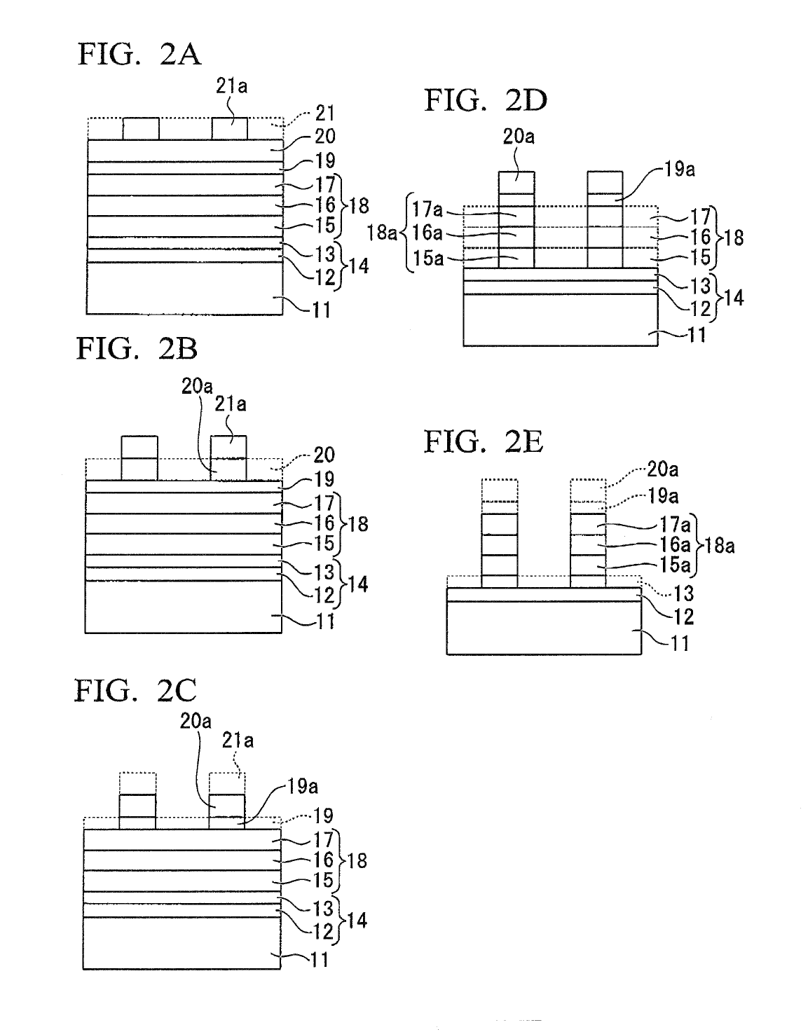

Next, a method for forming the memory element of the ferroelectric memory using the normal-temperature and high-temperature etching apparatus 1 will be described with reference to FIGS. 1 to 2E.

Firstly, as shown in FIG. 2A, an oxidized silicon (SiO₂) layer 12 and a titanium nitride (TiN) layer 13 are sequentially formed using a sputtering method, and a foundation layer 14 is thereby formed on a top face of a silicon substrate 11. The oxidized silicon (SiO₂) layer 12 may be formed by a chemical vapor deposition method.

Next, a lower electrode layer (first electrode layer) 15, a ferroelectric layer 16, and an upper electrode layer (second electrode layer) 17 are sequentially formed using a sputtering method, and a memory element layer 18 of a layered structure is thereby formed on the foundation layers 14 (process A, process B, and process C). The ferroelectric layer 16 may be formed by a method of application such as a sol-gel process or a chemical vapor deposition method. It is preferable that, as a conductor material constituting the lower electrode layer 15 and the upper electrode layer 17, an electrodes material having a noble metal including one, two, or more selected from the group consisting of platinum, iridium, ruthenium, rhodium, palladium, osmium, iridium oxide, ruthenium oxide, and strontium ruthenate be used. It is preferable that, as a ferroelectric material constituting the ferroelectric layer 16, one selected from the group consisting of PZT (Pb(Zr, Ti)O₃), SBT (SrBi₂Ta₂O₉), BTO (Bi₄Ti₃O₁₂), BLT ((Bi, La)₄Ti₃O₁₂), and BTO (BaTiO₃) be used.

Next, a titanium nitride (TiN) layer 19, and an oxidized silicon (SiO₂) layer 20 that is a material of a mask used when the ferroelectric layer 16 is formed are sequentially formed on the memory element layer 18 using a sputtering method. A photo resist 21 that is a material of a mask used when the oxidized silicon (SiO₂) layer 20 is etched is applied on the oxidized silicon (SiO₂) layer 20. By exposing and developing, a mask 21a having a predetermined pattern is formed on a region on which memory element will be formed. In this manner, the above-described multilayer film is formed on the silicon substrate 11. The multilayer film is etched at a high temperature and at a normal temperature as described below. In an explanation described below, the silicon substrate on which the multilayer film is formed is referred to the multilayer substrate.

Next, the multilayer substrate is imported to the transfer chamber 2 via the autoloader 9 and the import load lock chamber 7. The transfer mechanism provided to the transfer chamber 2 transfers the multilayer substrate to the normal-temperature etching chamber 3. In the normal-temperature etching chamber 3, as shown in FIG. 2B, the temperature of the silicon substrate 11 is maintained at a normal temperature, for example, in the range of 10° C. to 80° C., the oxidized silicon layer 20 is dry etched using the mask 21a, and a mask 20a that has a pattern identical to that of the mask 21a and made of oxidized silicon is thereby formed (process D). As an etching gas used for the dry etching, a mixture gas including, for example, argon (Ar), perfluorocarbon gas, oxygen (O₂) gas is preferably used. It is preferable that the flow rate ratio (Ar:CG:O₂) of argon (Ar), perfluorocarbon gas (CG), oxygen (O₂) gas in the mixture gas be 40 to 100:10:1 to 3. In addition, it is preferable that the pressure of the normal-temperature etching chamber 3 to which the mixture gas is supplied be in the range of 0.3 Pa to 3 Pa. As the perfluorocarbon gas, perfluoromethane (CF₄), perfluoroethane (C₂F₆), perfluoropropane (C₃F₈), hexafluorobutane (C₄F₆), octafluorocyclobutane (C₄F₈), perfluorocyclopentene (C₅F₈), or the like are preferably used. Specifically, considering the etching rate of the oxidized silicon layer 20 is high and the mask 21a is difficult to be etched, hexafluoro butane (C₄F₆), octafluorocyclobutane (C₄F₈), and perfluorocyclopentene (C₅F₈) whose carbon percentage is high are preferably used.

Next, as shown in FIG. 2C, the titanium nitride layer 19 is dry etched using the masks 21a and 20a while maintaining the temperature of the silicon substrate 11 at a normal temperature, for example, at 10° C. to 80° C., and a titanium nitride layer 19a having a pattern identical to that of the masks 21a and 20a is thereby formed. As an etching gas used for the dry etching, a halogen series gas is preferably used, and a mixture gas including, for example, chlorine (Cl₂) gas and boron chloride (BCl₃) gas is preferably used. It is preferable that the flow rate ratio (Cl₂:BCl₃) of chlorine (Cl₂) gas and boron chloride (BCl₃) gas in the mixture gas be 2:0 to 3. In addition, it is preferable that the pressure of the normal-temperature etching chamber 3 to which the mixture gas is supplied be in the range of 0.3 Pa to 3 Pa.

Next, the multilayer substrate is transferred to the ashing chamber 5, and the mask 21a is removed by ashing.

Next, the multilayer substrate is transferred to the pre-heat chamber 6, and preheated so that the temperature of the silicon substrate 11 is set in the range of 250° C. to 450° C., for example (process G).

Next, the multilayer substrate that has been preheated is transferred to the high-temperature etching chamber 4, the temperature of the silicon substrate 11 is maintained at in the range of, for example, 250° C. to 450° C. as shown in FIG. 2D, and the memory element layer 18 is dry etched at a high temperature using the mask 20a (process E). Firstly, the upper electrode layer 17 is dry etched at a high temperature using the mask 20a, and an upper electrode 17a having a pattern identical to that of the mask 20a is thereby formed. As an etching gas used for the dry etching, a halogen series gas is preferably used, and a mixture gas including, for example, hydrogen bromide (HBr) gas and oxygen (O₂) gas is preferably used. It is preferable that the flow rate ratio (HBr:O₂) of hydrogen bromide (HBr) gas and oxygen (O₂) gas in the mixture gas be 1:2 to 6. In addition, it is preferable that the pressure of the high-temperature etching chamber 4 to which the mixture gas is supplied be in the range of 0.3 Pa to 3 Pa.

Next, the ferroelectric layer 16 is dry etched at a high temperature using the mask 20a, a ferroelectric layer 16a having a pattern identical to that of the mask 20a is thereby formed. As an etching gas used for the dry etching, a halogen series gas is preferably used, and a mixture gas including, for example, argon (Ar) and boron chloride (BCl₃) gas is preferably used. It is preferable that the flow rate ratio (Ar:BCl₃) of argon (Ar) and boron chloride (BCl₃) gas in the mixture gas be 0 to 3:1. In addition, it is preferable that the pressure of the high-temperature etching chamber 4 to which the mixture gas is supplied be in the range of 0.3 Pa to 3 Pa.

Next, in a similar manner to form the upper electrode 17a, the lower electrode layer 15 is dry etched at a high temperature using the mask 20a, a lower electrode 15a having a pattern identical to that of the mask 20a is thereby formed. As an etching gas used for the dry etching, in a similar manner to form the upper electrode 17a, a halogen series gas such as a mixture gas including hydrogen bromide (HBr) gas and oxygen (O₂) gas is preferably used. It is preferable that the flow rate ratio (HBr:O₂) of hydrogen bromide (HBr) gas and oxygen (O₂) gas in the mixture gas be 1:2 to 6. In addition, it is preferable that the pressure of the high-temperature etching chamber 4 to which the mixture gas is supplied be in the range of 0.3 Pa to 3 Pa. In this manner, it is possible to form a memory element 18a having a layered structure.

Next, the multilayer substrate is transferred to the normal-temperature etching chamber 3, the temperature of the silicon substrate 11 is maintained at a normal temperature, for example, in the range of 10° C. to 80° C. as shown in FIG. 2E, the mask 20a is dry etched at a normal temperature, and the mask 20a is thereby removed (process F). As an etching gas used for the dry etching, a mixture gas including, for example, argon (Ar) and perfluorocarbon gas is preferably used. As the perfluorocarbon gas (CG), perfluoromethane (CF₄) is preferably used. It is preferable that the flow rate ratio (Ar:CG) of argon (Ar) and perfluorocarbon gas (CG) in the mixture gas be 1 to 9:1. In addition, it is preferable that the pressure of the normal-temperature etching chamber 3 to which the mixture gas is supplied be in the range of 0.3 Pa to 3 Pa.

Next, the titanium nitride layer 19a and the titanium nitride layer 13 are dry etched at a normal temperature while maintaining the temperature of the silicon substrate 11 at a normal temperature, for example, at 20° C. to 80° C., and exposed portions of the titanium nitride layer 19a and the titanium nitride layer 13 are thereby removed. As an etching gas used for the dry etching, a halogen series gas is preferably used, and a mixture gas including, for example, argon (Ar) and chlorine (Cl₂) gas is preferably used. It is preferable that the flow rate ratio (Ar:Cl₂) of argon (Ar) and chlorine (Cl₂) gas in the mixture gas be 0 to 2:1. In addition, it is preferable that the pressure of the normal-temperature etching chamber 3 to which the mixture gas is supplied be in the range of 0.3 Pa to 3 Pa. As a result, the oxidized silicon layer 12 is exposed except for portions on which the memory element 18a is formed.

Next, the multilayer substrate is transferred to the ashing chamber 5, the chlorine (Cl₂) gas in the mixture gas remaining in the multilayer substrate is removed.

In the above-described manner, on the top face of the silicon substrate 11 via the oxidized silicon layer 12, it is possible to form the memory element 18a in which the lower electrode 15a, the ferroelectric layer 16a, and the upper electrode 17a are sequentially stacked in layers.

The silicon substrate on which the memory element 18a is formed is exported to the exterior of the normal-temperature and high-temperature etching apparatus 1 via the export load lock chamber 8 and the autoloader 9.

As described above, according to the method for forming a memory element of a ferroelectric memory of the embodiment, processes that are the dry etching at a normal temperature, the dry etching at a high temperature, the ashing, the pre-heating, or the like are continuously performed under vacuum.

Therefore, it is possible to considerably shorten a time or the like for transfer between the processes, to eliminate the number of the processes, and to considerably shorten a manufacturing time. Therefore, it is possible to considerably reduce a cost required for manufacturing process. In addition, it is possible to continuously perform the process for forming the mask 20a made of the oxidized silicon (FIG. 2B), the process for forming the titanium nitride layer 19a (FIG. 2C), and the process for dry etching the memory element layer 18 at a high temperature (FIG. 2D) under reduced pressure. In addition, it is also possible to continuously perform the process for dry etching the memory element layer 18 at a high temperature (FIG. 2D) and the process for removing the mask 20a (FIG. 2E) under reduced pressure. Consequently, it is possible to effectively manufacture the memory element of the ferroelectric memory at a low cost in a short time as compared with conventional methods. The normal-temperature and high-temperature etching apparatus of the embodiment is constituted of the transfer chamber 2, the normal-temperature etching chamber 3, the high-temperature etching chamber 4, the ashing chamber 5, the pre-heat chamber 6, the import load lock chamber 7, and the export load lock chamber 8, that are that are coupled to the side walls of the transfer chamber 2, and the autoloader 9. Therefore, using one apparatus, it is possible to continuously perform the processes that are the dry etching at a normal temperature, the dry etching at a high temperature, the ashing, the pre-heating, or the like under vacuum, and it is possible to eliminate the time and cost required for all processes. As a result, it is possible to effectively manufacture the memory element of the ferroelectric memory at a low cost in a short time as compared with conventional methods.

In addition, in the embodiment, as an apparatus for manufacturing a device of the invention, for example, the normal-temperature and high-temperature etching apparatus is described. As the structure of the etching apparatus, a structure in which a normal-temperature etching chamber, a high-temperature etching chamber, and one or more load lock chambers are coupled to a transfer chamber including a transfer mechanism transferring a substrate is employed.

The invention is applicable to an etching apparatus including a structure except for the above-described normal-temperature and high-temperature etching apparatus.

What is claimed is:

1. A method for manufacturing a device, comprising:
(A) forming a first electrode layer on a substrate;
(B) forming a ferroelectric layer on the first electrode layer;
(C) forming a second electrode layer on the ferroelectric layer;
(D) forming a mask having a predetermined pattern on the second electrode layer;
(E) forming a memory element by selectively removing the first electrode layer, the ferroelectric layer, and the second electrode layer using the mask; and
(F) removing the mask, wherein
at least, the processes (D) and (E), or the processes (E) and (F) are continuously performed under a reduced pressure.

2. The method according to claim 1, wherein the process (D) and the process (F) are performed at a normal temperature, and the process (E) is performed at a high temperature.

3. The method according to claim 1, wherein the process (D), the process (E), and the process (F) are continuously performed under a reduced pressure.

4. The method according to claim 1, further comprising:
(G) preheating the substrate at a stage previous to the process (E).

5. The method according to claim 4, wherein a chamber in which the process (E) is performed is different from a chamber in which the process (G) is performed, and the process (E) and the process (G) are continuously performed under a reduced pressure.

6. The method according to claim 1, wherein a gas remaining in the substrate is removed at a stage subsequent to the process (F) in a chamber different from the chamber in which the process (F) is performed.

7. The method according to claim 1, wherein the first electrode layer and the second electrode layer includes one, two, or more selected from the group consisting of platinum, iridium, ruthenium, rhodium, palladium, osmium, iridium oxide, ruthenium oxide, and strontium ruthenate, and wherein the ferroelectric layer is one selected from the group consisting of PZT (Pb(Zr, Ti)O₃), SBT (SrBi₂Ta₂O₉), BTO (Bi₄Ti₃O₁₂), BLT ((Bi, La)₄Ti₃O₁₂), and BTO (BaTiO₃).

8. An apparatus for manufacturing a device, comprising:
a transfer chamber including a transfer mechanism transferring a substrate;
a normal-temperature etching chamber coupled to the transfer chamber;
a high-temperature etching chamber coupled to the transfer chamber; and
one or more load lock chambers coupled to the transfer chamber, wherein the transfer mechanism continuously transfers the substrate between the normal-temperature etching chamber, the high-temperature etching chamber, and the load lock chamber under vacuum.

9. The apparatus according to claim 8, further comprising:
an ashing chamber; and
a pre-heat chamber, wherein either or both of the ashing chamber and the pre-heat chamber is provided at the transfer chamber, and the transfer mechanism continuously transfers the substrate under vacuum between the ashing chamber, the pre-heat chamber, the normal-temperature etching chamber, the high-temperature etching chamber, and the load lock chamber.
